(19) United States
(12) Patent Application Publication
(10) Pub. No.: US 2023/0010289 A1
(43) Pub. Date: Jan. 12, 2023

(54) PHOTOVOLTAIC MODULE WITH MASKED INTERCONNECTS AND A METHOD OF MANUFACTURING THEREOF

(71) Applicant: Arka Energy Inc., Union City, CA (US)

(72) Inventors: VIKRANT A. CHAUDHARI, Bengaluru (IN); ANKIT IDWANI, Bhatapara (IN)

(21) Appl. No.: 17/860,847

(22) Filed: Jul. 8, 2022

(30) Foreign Application Priority Data
Jul. 8, 2021 (IN) 202111030715

(51) Int. Cl. H01L 31/18; H01L 31/0236

(52) U.S. Cl. CPC H01L 31/18; H01L 31/02366

(57) ABSTRACT

The present disclosure relates to a method for manufacturing thin, efficient, and aesthetically pleasing PV modules having masked or non-shiny interconnects. The method involves a step of applying a masking material over interconnects that are used for electrically connecting PV cells associated with the PV module. The masking material is in form or a strip or ribbon or paste adapted to be attached or applied over the interconnects, which saves the material and also restricts shining of the interconnects. Further, a clear glass superstrate is attached on top of the masked PV cells, and another glass substrate or polymer backsheet is attached to bottom of the masked PV cells. The masking material used is a chemical or radiation stable material, same as the material used for manufacturing the PV module, which restricts deterioration due to chemical reactions or UV light exposure.

### CROSS-REFERENCE TO RELATED APPLICATIONS

This application claims priority to India Application No. 202111030715, filed Jul. 8, 2021, the disclosure of which is incorporated herein by reference.

### TECHNICAL FIELD

The present disclosure relates to the field of solar panels or photovoltaic (PV) modules. More particularly, the present disclosure relates to a method for manufacturing thin, efficient, and aesthetically pleasing PV modules having masked or non-shiny interconnects, which do not deteriorate due to chemical reactions or UV light exposure.

### BACKGROUND

The rise in pollution and limited non-renewable sources available has led the world to switch towards renewable sources of energy. Solar energy is one such renewable energy that is easily available everywhere. Earlier, only industries, power sectors and government were using solar panels for harvesting solar energy, which was then transmitted to households and other infrastructures. However, due to the increase in energy demand and limited area available for installing solar panels, nowadays, general people are also installing solar panels on their private building structures.

Solar panels or photovoltaic (PV) modules are generally deployed in a wide variety of ways, including deployment over the roofs, sheds, and balconies of buildings, including private homes, commercial structures, and offices. The PV modules installed on residential roofs are preferred to match the appearance of the surrounding roof components. Such modules are required to be aesthetically pleasing to integrate them well with the roof to make them indistinguishable.

Conventional PV module 100 as shown in FIGS. 1 and 4 is fabricated using multiple PV cells 102, which are electrically connected using copper (Cu) interconnects 104. The PV cells 102 are electrically connected in series by the Cu interconnects 104, and are encapsulated between clear glass superstrate 106-2, and polymer substrate material (backsheet) 106-1 or another glass substrate 106-1. Further, encapsulating layer 108-2 is provided between the glass superstrate 106-2, and the top of the PV cells 102, and another encapsulating layer 108-1 is provided between the glass substrate/polymer substrate 106-1, and the bottom of the PV cells 102. However, the Cu interconnects 104 that is used for electrically connecting the PV cells 102 are coated with a layer of Tin and Lead (Sn/Pb) to facilitate soldering. The Sn/Pb coating provides a shiny appearance on these Cu interconnects 104 even though the PV modules 100 appear black or any other color. The shiny interconnects 104 reflect light and are visible from a distance as shown by white lines in FIG. 4, and in some cases, do not make a good aesthetic appeal and distort the appearance of the PV modules 100.

Some existing PV modules use black-colored Cu interconnects to reduce the shining of the Cu interconnects. However, the color on the Cu interconnects have been known to deteriorate over a period of time due to chemical reaction with the encapsulation material, and also due to exposure to Ultra Violet (UV) light. This makes such PV modules inefficient in restricting the shining of the Cu interconnects over a period.

Therefore, there is a need in the art to overcome the above-mentioned drawbacks, limitations, shortcomings associated with conventional PV modules, and provide a method for manufacturing thin, efficient, and aesthetically pleasing PV modules having masked and non-shiny interconnects, which do not deteriorate due to chemical reactions or UV light exposure.

### OBJECTS OF THE PRESENT DISCLOSURE

Some of the objects of the present disclosure, which at least one embodiment herein satisfies are as listed herein below.

It is an object of the present disclosure to provide an efficient, and aesthetically pleasing PV module having masked interconnects.

It is an object of the present disclosure to provide an efficient, and aesthetically pleasing PV module having masked interconnects, which does not deteriorate due to chemical reactions or UV light exposure.

It is an object of the present disclosure to provide an efficient, and aesthetically pleasing PV module whose interconnects do not shine or reflect light.

It is an object of the present disclosure to provide a method for manufacturing PV modules having masked interconnects to provide efficient, and aesthetically pleasing PV modules.

It is an object of the present disclosure to provide a method for manufacturing PV modules having masked interconnects to provide efficient, and aesthetically pleasing PV modules, which do not deteriorate due to chemical reactions or UV light exposure.

It is an object of the present disclosure to provide a method for manufacturing PV modules having masked interconnects to provide efficient, and aesthetically pleasing PV modules whose interconnects do not shine or reflect light.

It is an object of the present disclosure to save materials involved in the masking process of the interconnects of a PV module.

### SUMMARY

The present disclosure relates to the field of solar panels or photovoltaic (PV) modules. More particularly, the present disclosure relates to a method for manufacturing thin, efficient, and aesthetically pleasing PV modules having masked or non-shiny interconnects, which do not deteriorate due to chemical reactions or UV light exposure.

According to an aspect of the present disclosure, the proposed method and the PV module may involve multiple PV cells configured over a substrate. The PV cells may be electrically coupled to each other in a series connection using electrically conductive interconnects, generally made of copper and which may be coated with Lead or Tin (Sn/Pb) for soldering. The present invention may involve a step of application or masking a layer of masking material, on top of the Cu interconnects either manually or using an applicator such that the top surface of the interconnects is completely covered by the masking material. Further, a panel made of glass or a polymer material (PET backsheet) may be attached to the bottom of the masked PV cells, and another clear glass panel may be attached on top of the masked PV cells to provide the proposed PV module having masked or non-shiny interconnects.

In an aspect, the masking material applied or masked over the interconnects may be in form of a strip having a predefined thickness that may be adapted to be attached over the interconnects. The strip may have a predefined dimension greater than or equal to a dimension of interconnects such that the interconnects are completely covered by the strip of the masking material.

In an aspect, the dimension of the strip may be taken slightly wider than the dimension of the Cu interconnects to restrict movement of the strip during an encapsulation process. During, the encapsulation process, a layer of an encapsulating material selected from Ethylene Vinyl Acetate (EVA), or and Polyolefins (POE), may be applied as a filler between the masked PV cells, and the attached top glass panel, and the bottom glass panels or the PET backsheet.

In an aspect, the masking material may be made of the same material as used in the manufacturing of the PV module, preferably the encapsulation material such as Polyethylene Terephthalate (PET), Ethylene Vinyl Acetate (EVA), or and Polyolefins (POE), which are stable under chemical reactions or exposure to UV lights. The use of such material for masking in the proposed PV module restricts degradation of the applied masking material due to chemical reactions or exposure to UV lights. Moreover, these materials are traditionally used for manufacturing of solar modules and have been tested for UV exposure and chemical resistance. Further, the application or masking of the masking material only over the Cu interconnects, and not entirely over the PV modules (as in conventional PV modules) or on the top glass panel, saves the masking material required, restricts shining of the interconnects without hampering the efficiency of the PV modules, and makes the proposed PV module thin, and aesthetically pleasing.

Various objects, features, aspects, and advantages of the present disclosure will become more apparent from the following detailed description of preferred embodiments, along with the accompanying drawing figures in which like numerals represent like features.

Within the scope of this application, it is expressly envisaged that the various aspects, embodiments, examples and alternatives set out in the preceding paragraphs, in the claims and/or in the following description and drawings, and in particular the individual features thereof, may be taken independently or in any combination. Features described in connection with one embodiment are applicable to all embodiments, unless such features are incompatible.

### BRIEF DESCRIPTION OF DRAWINGS

The accompanying drawings are included to provide a further understanding of the present disclosure and are incorporated in and constitute a part of this specification. The drawings illustrate exemplary embodiments of the present disclosure and, together with the description, serve to explain the principles of the present disclosure. The diagrams are for illustration only, which thus is not a limitation of the present disclosure.

FIGS. 1 and 4 illustrate a cross-sectional side view and a front view, respectively of the existing conventional PV modules 100 available in the art.

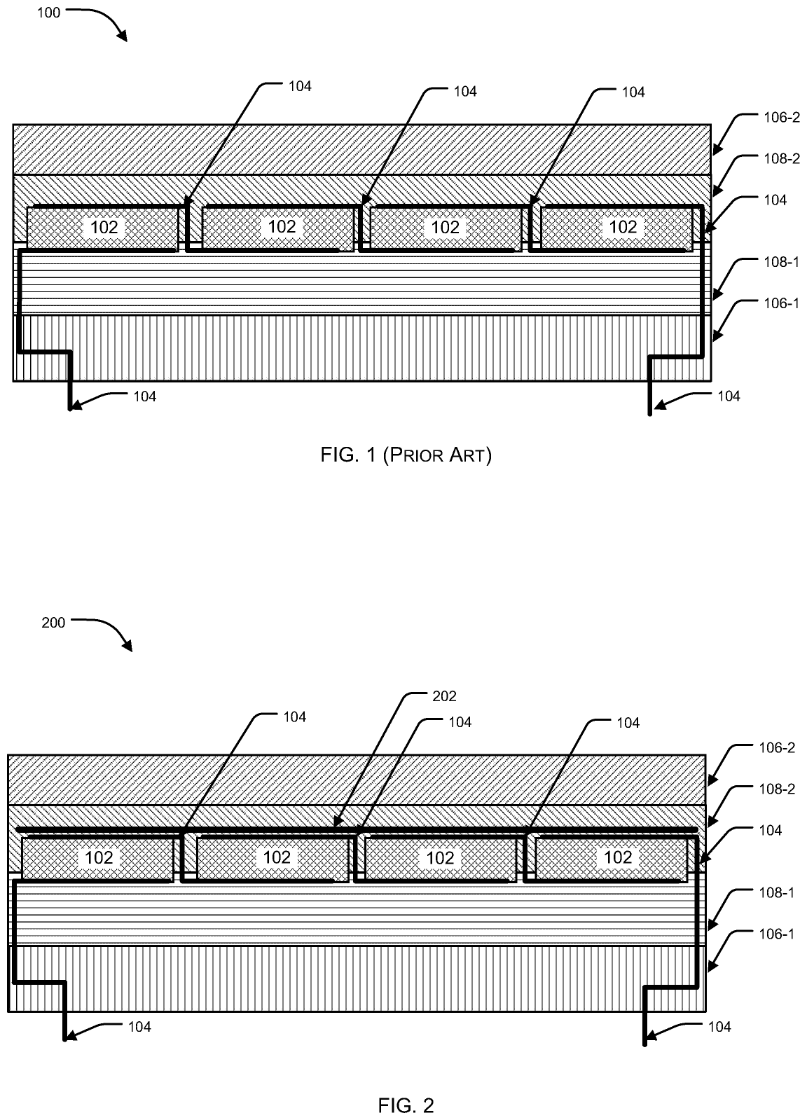

FIGS. 2 and 5 illustrate a cross-sectional side view, and a front view of the proposed PV module with masked interconnects in accordance with an embodiment of the present disclosure.

FIGS. 3A to 3C illustrate exemplary steps involved in the proposed method for manufacturing the PV module of FIGS. 2 and 5 in accordance with an embodiment of the present disclosure

### DETAILED DESCRIPTION

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims.

The present disclosure relates to the field of solar panels or photovoltaic (PV) modules. More particularly, the present disclosure relates to a method for manufacturing PV modules having masked or non-shiny interconnects to provide thin, efficient, and aesthetically pleasing PV modules, which do not deteriorate due to chemical reactions or UV light exposure.

According to an aspect, the present disclosure elaborates upon a method for manufacturing a photovoltaic (PV) module with masked interconnects. The method can include a step of applying or masking, a layer of a first polymer material, on top of one or more interconnects associated with one or more PV cells of the PV module, where the one or more interconnects can be configured over the one or more PV cells and can be used for electrical coupling of the corresponding PV cells. Further, the method can involve a step of attaching, a panel made of any or a combination of glass, and a second polymer material, over any or a combination of a top surface, and a bottom surface of the one or more masked PV cells to form the PV module with masked interconnects.

In an embodiment, the first polymer material, and the second polymer material can be selected from any or a combination of Polyethylene Terephthalate (PET), Ethylene Vinyl Acetate (EVA), and Polyolefins (POE) of required color.

In an embodiment, the first polymer material masked over the one or more interconnects can be in form of a strip having a predefined thickness that can be adapted to be attached to the one or more interconnects. The strip can have a predefined dimension based on a dimension of the one or more interconnects such that the one or more interconnects are completely covered by the strip of the first polymer material.

In an embodiment, the dimension of the strip can be taken slightly wider than the dimension of the one or more interconnects to restrict movement of the strip during an encapsulation process.

In an embodiment, the encapsulation process can include the step of applying a layer of an encapsulating material made of the same first polymer material, as a filler between the one or more masked PV cells, and the attached glass panel.

According to an aspect, the present disclosure elaborates upon a photovoltaic (PV) module with masked interconnects. The PV module can one or more PV cells electrically configured over a substrate. The one or more PV cells are electrically connected to each other using one or more interconnects. Further, a layer of first polymer material can be applied or masked on top of the one or more interconnects associated with one or more PV cells such that the one or more interconnects are completely covered or masked by the polymer material

In an embodiment, the PV module can include a panel made of any or a combination of glass, and a second polymer material, attached over any or a combination of a top surface, and a bottom surface of the one or more masked PV cells to form the PV module with masked interconnects.

In an embodiment, the layer of the first polymer material masked over the one or more interconnects can be in form of a strip having a predefined thickness that can be adapted to be attached over the one or more interconnects. The strip can have a predefined dimension based on a dimension of the one or more interconnects such that the one or more interconnects are completely covered by the strip of the first polymer material.

In an embodiment, the glass panel can be selected and attached to the top surface, and the bottom surface of the masked coated PV module as a glass substrate, and a glass superstate, respectively, for the PV module. Further, a polymer material panel can be selected and attached to the bottom surface of the masked PV cells as a backsheet for the PV module.

In an embodiment, the one or more interconnects can be made of electrically conductive materials selected from copper, and silver. Further, the one or more interconnects can be coated with Tin and Lead (Sn/Pb), and on top of which the first polymer material can be applied for masking the shiny Sn/PB coated interconnects.

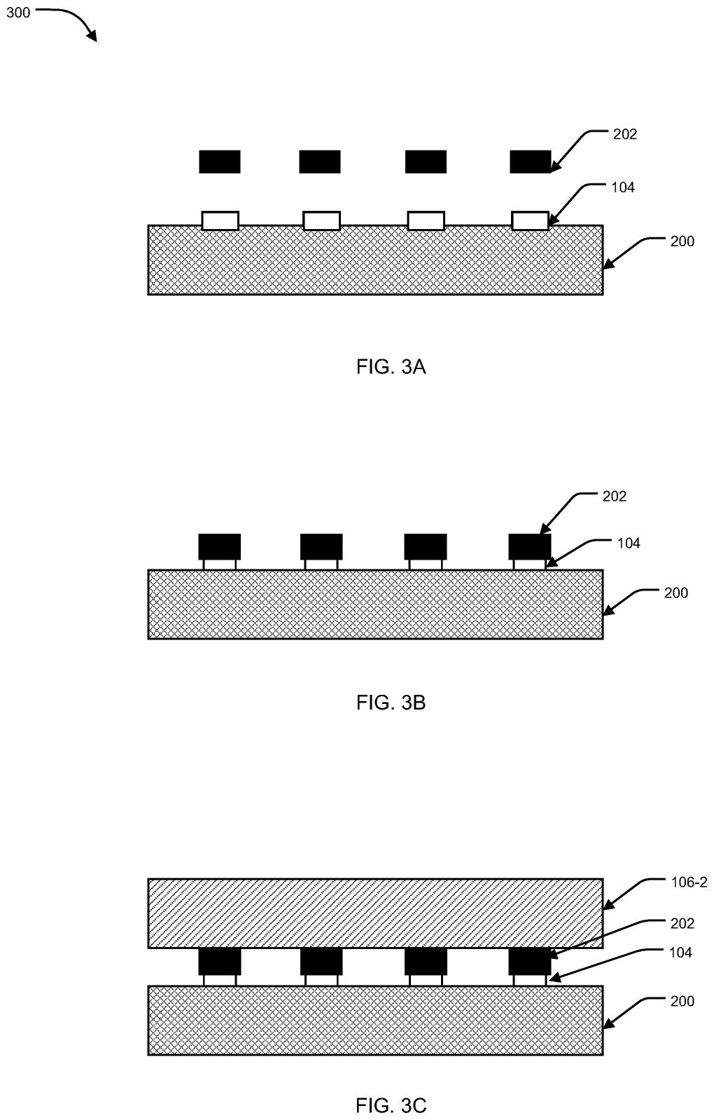

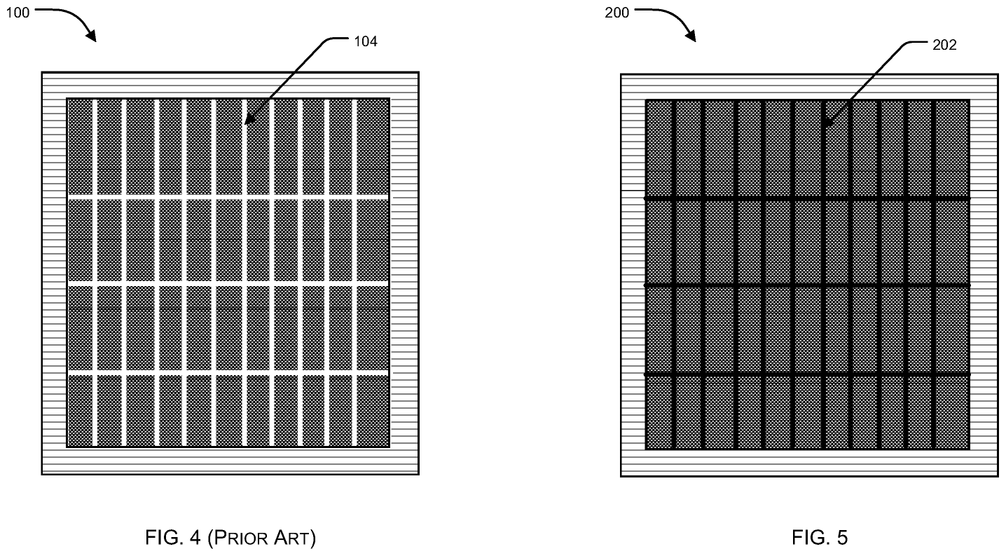

Referring to FIGS. 2 to 3C, according to an aspect, the proposed PV module 200 can include multiple PV cells 102 configured over a substrate. The PV cells 102 can be electrically coupled to each other in a series connection using electrically conductive interconnects 104, which can be made of copper or silver, and the likes, which is further coated with Lead or Tin (Sn/Pb) for soldering. The PV module 100 can include a layer of first polymer material 202 (also referred to as masking material 202, herein), on top of the interconnects 104 either manually or using an applicator such that the top surface of the interconnects 104 is completely covered by the masking material 202. Further, a panel made of glass 106-1 or a polymer material (PET backsheet) 106-1 can be attached to the bottom of the masked PV cells, and another clear glass panel 106-2 can be attached on top of the masked PV cells to provide the proposed PV module 200 having masked or non-shiny interconnects.

In an embodiment, the masking material 202 applied or masked over the interconnects can be in form of a strip or ribbon having a predefined thickness that can be adapted to be attached over the interconnects 104 using an adhesive, and the likes. The strip 202 can have a predefined dimension wider than or equal to the dimension of interconnects 104 such that the interconnects 104 are completely covered by the strip of the masking material 202.

In an embodiment, the dimension of the strip 202 can be taken slightly wider than the dimension of the interconnects 104 to restrict movement of the strip during an encapsulation process. An encapsulation process can be done over the masked PV cells 200, which applies a layer of an encapsulating material 108-1 and 108-2 as a filler between the masked PV cells 200, and the top glass panel 106-2, and the bottom glass panels or the PET backsheet 106-1.

In an embodiment, the masking material 202, and the encapsulating material 108-1 and 108-2 can be the same material as used in the manufacturing of the PV module 200, preferably Polyethylene Terephthalate (PET), Ethylene Vinyl Acetate (EVA), or Polyolefins (POE), which are resistant to chemical reactions or exposure to UV lights.

Referring to FIG. 3A to 3B, according to another aspect, the proposed method 300 for manufacturing the proposed PV module 200 of FIGS. 2 and 5, can include a step of configuring multiple PV cells over a substrate, followed by electrically connecting the PV cells in series via electrically conductive interconnects 104 which may be coated with Sn/Pb. The proposed method 300 can include a step of applying or masking, either manually or using an applicator, a layer of a first polymer material 202 (masking material), on top of interconnects 104 associated with the PV module 200 as shown in FIGS. 3A and 3B.

In an embodiment, the masking material 202 can be in form of a thin strip or ribbon, having a predefined thickness and adapted to be attached on top of the interconnects 104 using an adhesive material. The strip or ribbon 202 can have a predefined dimension based on a dimension of the interconnects such that the interconnects 104 are completely covered by the strip of the first polymer material 202. In an exemplary embodiment, the dimension of the strip 202 can be taken slightly wider than the dimension of the interconnects to restrict movement of the strip during an encapsulation process.

In an embodiment, the proposed method 300 can further include a step of attaching, a clear glass panel 106-2 over a top surface of the masked PV cells of FIG. 3A to form the PV module 200 with masked interconnects 104 as shown in FIG. 3C. In an exemplary embodiment, the glass panel 106-1 can be attached to the top surface as a superstate, and another glass panel or backsheet can be attached to a bottom surface of the masked PV module 200 as a substrate of the PV module 200.

In an embodiment, the proposed method 300 can further include an encapsulation step, where a layer of an encapsulating material made of the same first polymer material, is applied as a filler between the masked PV cells, and the attached top and bottom glass panel.

In an embodiment, the masking material, and the encapsulating material used in the proposed method 300 can be made of the same material as used in the manufacturing of the PV module, preferably Polyethylene Terephthalate (PET), Ethylene Vinyl Acetate (EVA), or Polyolefins (POE), which are resistant to chemical reactions or exposure to UV lights

Accordingly, the use of a thin layer or sheet or strip of stable polymeric material 202 for masking the interconnects in the proposed PV module 200 and the proposed method 300 restricts degradation of the applied masking material 202 due to chemical reactions or exposure to UV lights. Further, the application of the masking material 202 only over the interconnects 104, and not entirely over the PV modules 200 (as in conventional PV modules) or on the top glass panel 106-1, saves the masking material required, restricts the shining of the interconnects 104 (as shown by dark black lines in FIG. 5) without much impact on the efficiency of the PV modules 200, and also makes the proposed PV module 100 thin, and aesthetically pleasing.

Those skilled in the art would appreciate that embodiments of the present disclosure utilize various novel and inventive features by providing a method for manufacturing thin, efficient, and aesthetically pleasing PV modules having masked or non-shiny interconnects, which do not deteriorate due to chemical reactions or UV light exposure.

Further, it is to be appreciated by a person skilled in the art that while various embodiments and drawings of the present disclosure have been elaborated by showing a limited number of PV cells, interconnects, panels, and the masking material, and a limited number of layers of these materials/components in the proposed PV module, however, the limited number of components or layers are not just limited to the given number but can be of any number based on the requirement of the user, and all such embodiments are well within the scope of the present disclosure.

While some embodiments of the present disclosure have been illustrated and described, those are completely exemplary in nature. The disclosure is not limited to the embodiments as elaborated herein only and it would be apparent to those skilled in the art that numerous modifications besides those already described are possible without departing from the inventive concepts herein. All such modifications, changes, variations, substitutions, and equivalents are completely within the scope of the present disclosure. The inventive subject matter, therefore, is not to be restricted except in the spirit of the appended claims.

### Advantages of the Present Invention

The present invention provides an efficient, and aesthetically pleasing PV module having masked or non-shiny interconnects.

The present invention provides an efficient, and aesthetically pleasing PV module having masked interconnects, which does not deteriorate due to chemical reactions or UV light exposure.

The present invention provides an efficient, and aesthetically pleasing PV module whose interconnects do not shine or reflect light.

The present invention provides a method for manufacturing PV modules having masked interconnects to provide efficient, and aesthetically pleasing PV modules.

The present invention provides a method for manufacturing PV modules having masked interconnects to provide efficient, and aesthetically pleasing PV modules, which do not deteriorate due to chemical reactions or UV light exposure.

The present invention provides a method for manufacturing PV modules having masked interconnects to provide efficient, and aesthetically pleasing PV modules whose interconnects do not shine or reflect light.

The present invention saves materials involved in the masking process of the interconnects of a PV module.

We claim:

1. A method for manufacturing a photovoltaic (PV) module with masked interconnects, the method comprising the steps of:
applying or masking a layer of a first polymer material, wherein the layer of the first polymer material is on top of one or more interconnects associated with one or more PV cells of the PV module, wherein the one or more interconnects are configured over the one or more PV cells and are used for electrical coupling of the corresponding PV cells; and
attaching a panel made of any or a combination of glass and a second polymer material, over a top surface of the one or more masked PV cells, a bottom surface of the one or more masked PV cells, or combinations thereof, to form the PV module with masked interconnects.

2. The method as claimed in claim 1, wherein the first polymer material, and the second polymer material are selected from Polyethylene Terephthalate (PET), Ethylene Vinyl Acetate (EVA), and Polyolefins (POE) of required color, and combinations thereof.

3. The method as claimed in claim 1, wherein the first polymer material masked over the one or more interconnects is in form of a strip having a predefined thickness that is adapted to be attached to the one or more interconnects, wherein the strip has a predefined dimension based on a dimension of the one or more interconnects, wherein the one or more interconnects are completely covered by the strip of the first polymer material.

4. The method as claimed in claim 3, wherein the dimension of the strip is wider than the dimension of the one or more interconnects to restrict movement of the strip during an encapsulation process.

5. The method as claimed in claim 4, wherein the encapsulation process comprises the step of applying a layer of an encapsulating material made of the first polymer material, wherein the encapsulating material is a filler between the one or more masked PV cells and the corresponding attached glass panel.

6. A photovoltaic (PV) module with masked interconnects, the PV module comprising:
one or more PV cells electrically configured over a substrate, wherein the one or more PV cell are electrically connected to each other using one or more interconnects; and
a layer of first polymer material applied or masked on top of the one or more interconnects associated with one or more PV cells, wherein the one or more interconnects are completely covered or masked by the polymer material.

7. The PV module as claimed in claim 6, wherein the PV module comprises a panel made of glass, a second polymer material, and combinations thereof, wherein the panel is attached over a top surface of the one or more masked PV cells, a bottom surface of the one or more masked PV cells, or combinations thereof, to form the PV module with masked interconnects.

8. The PV module as claimed in claim 6, wherein the layer of the first polymer material masked over the one or more interconnects is in a form of a strip having a predefined thickness that is adapted to be attached over the one or more interconnects, wherein the strip has a predefined dimension based on a dimension of the one or more interconnects, wherein the one or more interconnects are completely covered by the strip of the first polymer material.

9. The PV module as claimed in claim 6, wherein a glass panel is attached to the top surface, and the bottom surface of the masked PV module wherein a second polymer material panel is attached to the bottom surface of the masked PV cells as a backsheet for the PV module.

10. The PV module as claimed in claim 6, wherein the one or more interconnects are made of electrically conductive materials selected from copper, and silver, and wherein the one or more interconnects are coated with Tin, Lead, or combinations thereof, wherein the first polymer material is applied on top of the one or more interconnects.
